(19) United States
(12) Patent Application Publication
(10) Pub. No.: US 2024/0405008 A1
(43) Pub. Date: Dec. 5, 2024

(54) DISPLAY PANEL AND DISPLAY APPARATUS

(71) Applicant: Wuhan Tianma Microelectronics Co., Ltd., Wuhan (CN)

(72) Inventors: Chao YU, Wuhan (CN); Fei LI, Wuhan (CN); Dian ZHANG, Wuhan (CN); Fang CHEN, Wuhan (CN)

(21) Appl. No.: 18/807,380

(22) Filed: Aug. 16, 2024

(30) Foreign Application Priority Data
Feb. 4, 2024 (CN) 202410160083.4

(51) Int. Cl. H01L 25/16; H01L 27/12; H01L 27/15; H01L 33/62

(52) U.S. Cl. CPC H01L 25/167; H01L 27/1244; H01L 27/1255; H01L 27/156; H01L 33/62

(57) ABSTRACT

Embodiments of the present disclosure provide a display panel and a display apparatus. The display panel includes: a substrate; a plurality of pixel circuits, a plurality of light-emitting devices, and a first signal line that are located on a side of the substrate. An output terminal of each of the pixel circuits is electrically connected to a first electrode of one of the light-emitting devices, and a second electrode of each of the plurality of light-emitting devices is electrically connected to the first signal line; and the first signal line comprises first portions and second portions provided in different layers and electrically connected, the first portions extend along a first direction, the second portions extend along a second direction, and the first direction intersects the second direction. The first signal line is of a grid-like structure, and thus a signal transmitted therethrough has a smaller voltage drop.

### CROSS-REFERENCE TO RELATED DISCLOSURES

The present application claims priority to Chinese Patent Application No. 202410160083.4, filed on Feb. 4, 2024, the content of which is incorporated herein by reference in its entirety.

### TECHNICAL FIELD

The present disclosure relates to the field of display technology, and in particular, to a display panel and a display apparatus.

### BACKGROUND

With the development of the display industry, the market demand for a high-resolution, low-cost, and low-power consumption display panel is growing. One reason for high power consumption in an existing display panel is a large voltage drop on a signal line transmitting a supply voltage for a pixel circuit. To ensure that the pixel circuit obtains a more ideal supply voltage, the value of the supply voltage output by a chip should be increased, which may lead to the high power consumption of the display panel. Alternatively, the width of the signal line transmitting the supply voltage should be increased, which may affect the resolution of the display panel and increase the difficulty in designing the display panel.

### SUMMARY

In view of this, embodiments of the present disclosure provide a display panel and a display apparatus to resolve the above problem.

In a first aspect, an embodiment of the present disclosure provides a display panel, including: a substrate; a plurality of pixel circuits, a plurality of light-emitting devices, and a first signal line that are located on a side of the substrate. An output terminal of each of the pixel circuits is electrically connected to a first electrode of one of the light-emitting devices, and a second electrode of each of the plurality of light-emitting devices is electrically connected to the first signal line. The first signal line includes first portions and second portions provided in different layers and electrically connected, the first portions extend along a first direction, the second portions extend along a second direction, and the first direction intersects the second direction.

In a second aspect, based on the same inventive concept, an embodiment of the present disclosure provides a display apparatus including a display panel including: a substrate; a plurality of pixel circuits, a plurality of light-emitting devices, and a first signal line that are located on a side of the substrate; where an output terminal of each of the pixel circuits is electrically connected to a first electrode of one of the light-emitting devices, and a second electrode of each of the plurality of light-emitting devices is electrically connected to the first signal line; and the first signal line includes first portions and second portions provided in different layers and electrically connected, the first portions extend along a first direction, the second portions extend along a second direction, and the first direction intersects the second direction.

### BRIEF DESCRIPTION OF DRAWINGS

To describe the technical solutions in the embodiments of the present disclosure more clearly, the following briefly describe the accompanying drawings required for describing the embodiments. Apparently, the accompanying drawings in the following description are merely some embodiments of the present disclosure, and those of ordinary skill in the art may still derive other accompanying drawings from these accompanying drawings without creative efforts.

FIG. 1 is a schematic diagram of a partial region of a display panel provided by an embodiment of the present disclosure;

FIG. 2 is a schematic cross-sectional view taken along a direction A1-A2 shown in FIG. 1;

FIG. 3 is an equivalent circuit diagram of a pixel circuit included in a display panel provided by an embodiment of the present disclosure;

FIG. 4 is a schematic diagram of a display panel provided by an embodiment of the present disclosure;

FIG. 5 is a schematic cross-sectional view taken along a direction B1-B2 shown in FIG. 4;

FIG. 6 is another schematic cross-sectional view taken along the direction B1-B2 shown in FIG. 4;

FIG. 7 is a schematic diagram of a display panel provided by an embodiment of the present disclosure;

FIG. 8 is a schematic cross-sectional view taken along a direction C1-C2 shown in FIG. 7;

FIG. 9 is another schematic cross-sectional view taken along the direction C1-C2 shown in FIG. 7;

FIG. 10 is another schematic diagram of a display panel provided by an embodiment of the present disclosure;

FIG. 11 is a schematic cross-sectional view taken along a direction D1-D2 shown in FIG. 10;

FIG. 12 is another schematic cross-sectional view taken along the direction C1-C2 shown in FIG. 7;

FIG. 13 is another schematic cross-sectional view taken along the direction C1-C2 shown in FIG. 7;

FIG. 14 is a schematic layout of a display panel provided by an embodiment of the present disclosure;

FIG. 15 is another schematic layout of a display panel provided by an embodiment of the present disclosure;

FIG. 16 is another schematic diagram of a display panel provided by an embodiment of the present disclosure;

FIG. 17 is a schematic cross-sectional view taken along a direction A1-A2 shown in FIG. 16;

FIG. 18 is another schematic layout of a display panel provided by an embodiment of the present disclosure;

FIG. 19 is a schematic diagram of a part of a structure in FIG. 18;

FIG. 20 is another schematic diagram of a part of the structure in FIG. 18;

FIG. 21 is another schematic diagram of a display panel provided by an embodiment of the present disclosure;

FIG. 22 is a schematic cross-sectional view taken along a direction G1-G2 shown in FIG. 21;

FIG. 23 is a schematic diagram of a partial structure in a display panel provided by an embodiment of the present disclosure;

FIG. 24 is a schematic diagram of a display panel provided by an embodiment of the present disclosure;

FIG. 25 is another schematic layout of a display panel provided by an embodiment of the present disclosure;

FIG. 26 is another schematic diagram of a display panel provided by an embodiment of the present disclosure;

FIG. 27 is an equivalent circuit diagram of a pixel circuit included in a display panel provided by an embodiment of the present disclosure;

FIG. 28 is another schematic layout of a display panel provided by an embodiment of the present disclosure;

FIG. 29 is a schematic cross-sectional view taken along a direction S1-S2 shown in FIG. 28;

FIG. 30 is another schematic layout of a display panel provided by an embodiment of the present disclosure;

FIG. 31 is another schematic layout of a display panel provided by an embodiment of the present disclosure;

FIG. 32 is another schematic layout of a display panel provided by an embodiment of the present disclosure;

FIG. 33 is another schematic layout of a display panel provided by an embodiment of the present disclosure;

FIG. 34 is another schematic layout of a display panel provided by an embodiment of the present disclosure;

FIG. 35 is another schematic layout of a display panel provided by an embodiment of the present disclosure; and

FIG. 36 is a schematic diagram of a display apparatus provided by an embodiment of the present disclosure.

### DETAILED DESCRIPTION OF THE EMBODIMENTS

For a better understanding of the technical solutions of the present disclosure, the following describes in detail the embodiments of the present disclosure in conjunction with the accompanying drawings.

It should be noted that, the described embodiments are merely some but not all of the embodiments of the present disclosure. Based on the embodiments of the present disclosure, all other embodiments obtained by those of ordinary skill in the art without creative efforts fall within the protection scope of the present disclosure.

Terms in the embodiments of the present disclosure are merely used to describe the specific embodiments and are not intended to limit the present disclosure. Unless otherwise specified in the context, words, such as “a”, “the”, and “this”, in a singular form in the embodiments and appended claims of the present disclosure are intended to comprise plural forms.

It should be understood that the term “and/or” used in this specification merely describes associations between associated objects, and it indicates three types of relationships. For example, A and/or B may indicate that A exists alone, A and B coexist, or B exists alone. In addition, the character “/” used in this specification generally indicates that the associated objects are in an “or” relationship.

In the description of this specification, it should be understood that the terms such as “substantially”, “approximate to”, “approximately”, “about”, “roughly”, and “in general” described in the claims and embodiments of the present disclosure mean general agreement within a reasonable process operation range or tolerance range, rather than an exact value.

It should be understood that although the terms such as first and second may be used to describe signal lines in the embodiments of the present disclosure, these signal lines should not be limited by these terms. These terms are used only to distinguish between the signal lines from each other. For example, without departing from the scope of the embodiments of the present disclosure, a first signal line may also be referred to as a second signal line, and similarly, the second signal line may also be referred to as the first signal line.

It is obvious for those of ordinary skill in the art that various modifications and changes may be made to the present disclosure without departing from the spirit or scope of the present disclosure. Therefore, the present disclosure is intended to cover the modifications and changes of the present disclosure that fall within the scope of the corresponding claims (technical solutions claimed) and equivalents thereof. It should be noted that, the implementations provided in the embodiments of the present disclosure can be combined with each other if no conflict occurs.

The applicant of the present disclosure provides a solution to the problem existing in the prior art through careful and in-depth research.

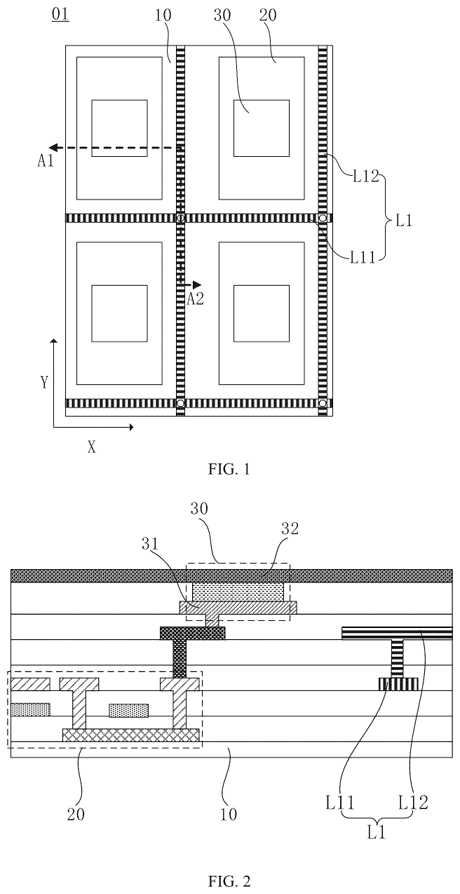

FIG. 1 is a schematic diagram of a partial region of a display panel provided by an embodiment of the present disclosure, and FIG. 2 is a schematic cross-sectional view taken along a direction A1-A2 shown in FIG. 1.

As shown in conjunction with FIG. 1 and FIG. 2, an embodiment of the present disclosure provides a display panel 01, including: a substrate 10; a plurality of pixel circuits 20, a plurality of light-emitting devices 30, and a first signal line L1 that are located on a side of the substrate 10. FIG. 2 shows only a partial structure of one of the pixel circuits 20. That is, in FIG. 2, the pixel circuit 20 is illustrated as a partial structure of the pixel circuit 20.

The light-emitting devices 30 may be any one of an organic light-emitting diode (OLED), a mini-light-emitting diode (mini-LED), and a micro-light-emitting diode (micro-LED).

As shown in FIG. 2, an output terminal of the pixel circuit 20 is electrically connected to a first electrode 31 of the light-emitting device 30. The pixel circuit 20 can provide a light-emitting drive current to the light-emitting device 30. The first electrode 31 of the light-emitting device 30 may be an anode, the output terminal of the pixel circuit 20 may be electrically connected to the anode of the light-emitting device 30 and provide the light-emitting drive current to the light-emitting device 30 through the anode of the light-emitting device 30. In addition, the first electrode 31 of the light-emitting device 30 may alternatively be a cathode.

Second electrodes 32 of the plurality of light-emitting devices 30 are electrically connected to the first signal line L1 (not shown), the first signal line L1 can provide required signals to the second electrodes 32 of the plurality of light-emitting devices 30 at the same time. Optionally, the first signal line L1 may provide a supply voltage for the second electrode 32 of the light-emitting device 30. When the first electrode 31 of the light-emitting device 30 is an anode, the second electrode 32 of the light-emitting device 30 may be a cathode, and the first signal line L1 may provide a supply voltage VEE of a low potential for the second electrode 32 of the light-emitting device 30. In addition, when the first electrode 31 of the light-emitting device 30 is a cathode, the second electrode 32 of the light-emitting device 30 may be an anode, and the first signal line L1 may provide a supply voltage VDD of a high potential for the second electrode 32 of the light-emitting device 30.

In the embodiment of the present disclosure, the first signal line L1 includes first portions L11 and second portions L12 provided in different layers and electrically connected. The first portions L11 extend along a first direction X, and the second portions L12 extend along a second direction Y. The first direction X intersects the second direction Y. Optionally, the first direction X may be perpendicular to the second direction Y. It should be noted that, the first portions L11 extending along the first direction X means that an overall extension direction of the first portions L11 is the first direction X, and the first portions L11 may include bent parts; and the second portions L12 extending along the second direction Y means that an overall extension direction of the second portions L12 is the second direction Y, and the second portions L12 may include bent part.

The first signal line L1 may have a grid-like structure, and in the grid-like structure, at least a portion extending along the first direction X and at least a portion extending along the second direction Y may be located in different layers. That is to say, the signal line that provides the supply voltage for the second electrode 32 of the light-emitting device 30 may be a grid-like structure including portions located in different layers.

In the embodiment of the present disclosure, by setting the first signal line L1 in a grid-like structure, it is possible to reduce the voltage drop of the first signal line L1.

If the portions of the first signal line L1 of the grid-like structure are in a same film layer, it is necessary to consider providing the grid-like structure in a separate conductive film layer to avoid the grid-like structure being short-circuited by other signal lines. That is, a new conductive film layer needs to be added, which will cause the panel thickness of the display panel 01 to increase and also the preparation cost and manufacturing process of the display panel 01 to increase.

Whereas, if the first portions L11 and the second portions L12 extending along different directions of the first signal line L1 are provided in different conductive film layers, the first portions L11 may be located in a same film layer as another conductive structure, and the second portions L12 may be located in a same film layer as another conductive structure, which may neither increase the thickness of the display panel 01 nor increase manufacturing process or cost.

In addition, since the first signal line L1 is electrically connected to the second electrode 32 of the light-emitting device 30, that is, the first signal line L1 is configured to transmit a substantially constant supply voltage, and the first portions L11 and the second portions L12 of the first signal line L1 are provided in different film layers, the performance of signal lines or functional devices in a same layer as and/or in a layer adjacent to the first portions L11 and the second portions L12, respectively, may not be substantially affected.

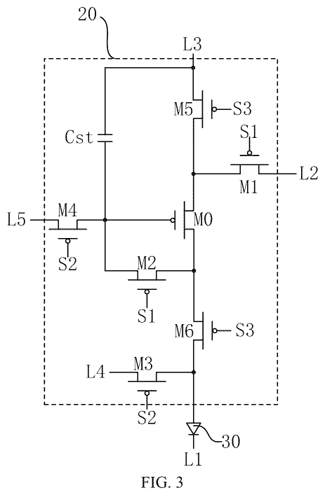

FIG. 3 is an equivalent circuit diagram of a pixel circuit included in a display panel provided by an embodiment of the present disclosure.

As shown in FIG. 3, the pixel circuit 20 provided by the embodiment of the present disclosure includes a drive transistor M0, a data write transistor M1, a threshold write transistor M2, a first reset transistor M3, a second reset transistor M4, a power supply write transistor M5, a light-emitting control transistor M6, and a storage capacitor Cst. An output terminal of the pixel circuit 20 is electrically connected to a first electrode of a light-emitting device 30. A second electrode of the light-emitting device 30 is electrically connected to the first signal line L1.

The data write transistor M1 has a first electrode electrically connected to a data line L2, a second electrode electrically connected to a first electrode of the drive transistor M0, and a gate electrically connected to a first scanning line S1. The threshold write transistor M2 has a first electrode electrically connected to a second electrode of the drive transistor MO, a second electrode electrically connected to a gate of the drive transistor M0, and a gate electrically connected to the first scanning line S1. The first reset transistor M3 has a first electrode electrically connected to a first reset line L4, a second electrode electrically connected to the first electrode 31 of the light-emitting device 30, and a gate electrically connected to a second scanning line S2. The second reset transistor M4 has a first electrode electrically connected to a second reset line L5, a second electrode electrically connected to the gate of the drive transistor M0, and a gate electrically connected to the second scanning line S2. The power supply write transistor M5 has a first electrode electrically connected to a supply voltage line L3, a second electrode electrically connected to the first electrode of the drive transistor M0, and a gate electrically connected to a third scanning line S3. The light-emitting control transistor M6 has a first electrode electrically connected to the second electrode of the drive transistor M0, a second electrode electrically connected to the first electrode of the light-emitting device 30, and a gate electrically connected to the third scanning line S3. The storage capacitor Cst has one electrode plate electrically connected to the supply voltage line L3 and the other electrode plate electrically connected to the gate of the drive transistor M0.

It should be noted that, the first electrodes of the first reset transistor M3 and the second reset transistor M4 may be electrically connected to different reset lines, respectively, or the first electrodes of the first reset transistor M3 and the second reset transistor M4 may be connected to a same reset line.

An operation cycle of the pixel circuit 20 includes a reset stage, a data writing stage, and a light-emitting stage. In the reset stage, the second scanning line S2 transmits an enable signal, the first reset transistor M3 and the second reset transistor M4 are turned on, and a reset voltage transmitted through the first reset line L4 and a reset voltage transmitted through the second reset line L5 are transmitted to the first electrode 31 of the light-emitting device 30 and the gate of the drive transistor MO, respectively. In the data writing stage, the first scanning line S1 transmits an enable signal, the data write transistor M1 and the threshold write transistor M2 are turned on, a data voltage transmitted through the data line L2 is transmitted to the gate of the drive transistor M0, and the storage capacitor Cst enables the gate of the drive transistor M0 to maintain the received data voltage. In the light-emitting stage, the third scanning line S3 transmits an enable signal, the supply voltage writing transistor M5 and the light-emitting control transistor M6 are turned on, and the first signal line L1 and the supply voltage line L3 transmit different supply voltages, enabling the drive transistor M0 to generate a drive current and the drive current flows through the light-emitting device 30.

In the pixel circuit 20 shown in FIG. 3, the first signal line L1 and the supply voltage line L3 are configured to transmit different supply voltages, respectively. For example, the first signal line L1 may be configured to transmit a supply voltage VEE of a low potential, and the supply voltage line L3 may be configured to transmit a supply voltage VDD of a high potential.

It should be noted that, the pixel circuit shown in FIG. 3 is merely an illustration, and the inventive concept of the present disclosure is also applicable to the case where the display panel 01 includes other pixel circuits 20. For ease of understanding, the following embodiment is described by taking the pixel circuit 20 show in FIG. 3 as an example. However, structures (such as a transistor and a signal line connected thereto) related to the pixel circuit 20 involved in the following embodiment are not limited to the illustration in FIG. 3.

In the embodiment of the present disclosure, the second portions L12 of the first signal line L1 may be located on a side of the first portions L11 away from the substrate 10.

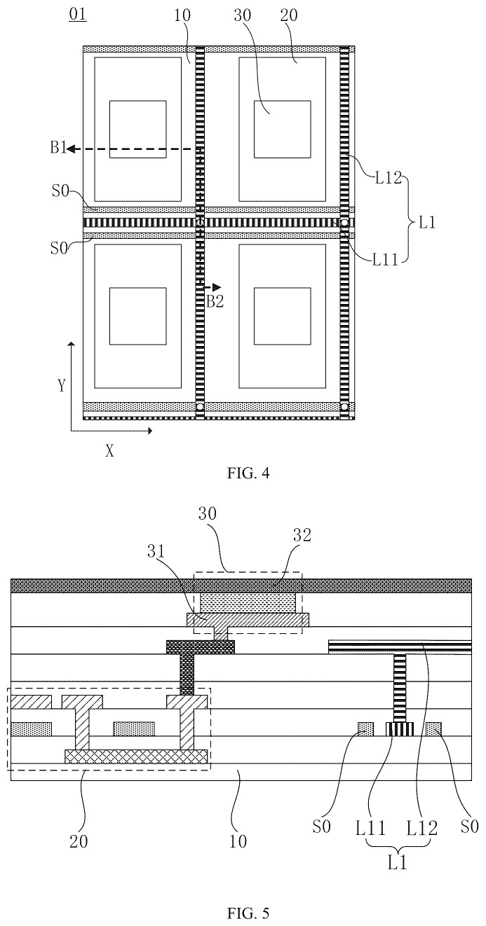

FIG. 4 is a schematic diagram of a display panel provided by an embodiment of the present disclosure, and FIG. 5 is a schematic cross-sectional view taken along a direction B1-B2 shown in FIG. 4.

In a technical solution corresponding to the embodiment, as shown in FIG. 4, the display panel 01 further includes a plurality of scanning lines S0 extending along the first direction X. The plurality of scanning lines S0 extending along the first direction X may include at least one of the first scanning line S1, the second scanning line S2, and the third scanning line S3. For example, the plurality of scanning lines S0 extending along the first direction X may include the first scanning line S1, the second scanning line S2, and the third scanning line S3.

In the present technical solution, as shown in FIG. 5, the first portion L11 of the first signal line L1 and the scanning lines SO are located in a same film layer, and the first portion L11 of the first signal line L1 and the scanning lines S0 have a same extension direction and are provided in a same layer. Since the number of the scanning lines S0 extending along the first direction X in the display panel 01 is larger, that is, the number of the scanning lines S0 arranged along the second direction Y is larger, and providing the first portion L11 of the first signal line L1 and the scanning lines S0 in a same layer and in a same direction requires only a slight adjustment of the arrangement of the plurality of scanning lines S0, the layout design of the pixel circuit 20 is less difficult.

As shown in FIG. 5, the second portion L12 of the first signal line L1 is located on a side of the film layer of the first portion L11 away from the substrate 10. Usually, the scanning lines S0 are in a conductive film layer in the display panel 01 closest to or relatively close to the substrate 10. When the first portion L11 of the first signal line L1 is provided in the same layer as the scanning lines S0 and the second portion L12 is provided on a side of the scanning lines S0 away from the substrate 10, it is possible for the film layer where the second portions L12 is provided to have more options, or it is possible to provide the second portion L12 in a more desirable film layer as needed.

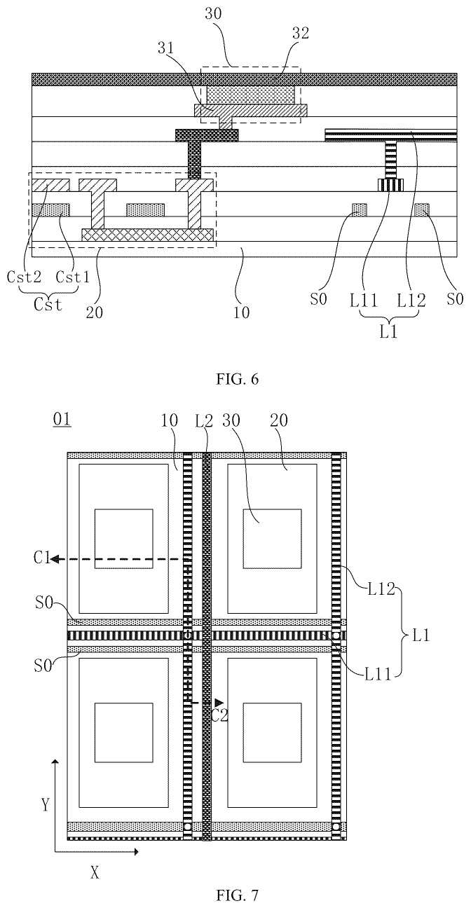

FIG. 6 is another schematic cross-sectional view taken along the direction B1-B2 shown in FIG. 4.

In a technical solution corresponding to the embodiment, the pixel circuit 20 includes a drive transistor M0 and a storage capacitor Cst. As shown in FIG. 6, the storage capacitor Cst includes a first electrode plate Cst1 and a second electrode plate Cst2. The first electrode plate Cst1 and the second electrode plate Cst2 of the storage capacitor Cst are provided in different layers. The first electrode plate Cst1 of the storage capacitor Cst and a gate of the drive transistor M0 are provided in a same layer and electrically connected. A part of the first electrode plate Cst1 of the storage capacitor Cst may be considered as the gate of the drive transistor M0.

In the technical solution, as shown in FIG. 6, the first portion L11 of the first signal line L1 and the second electrode plate Cst2 of the storage capacitor Cst are located in a same film layer. To ensure that a capacitance value of the storage capacitor Cst meets a requirement, the first electrode plate Cst1 and the second electrode plate Cst2 of the storage capacitor Cst are usually in adjacent conductive film layers of the display panel 01. The conductive film layer where the second electrode plate Cst2 is located is a conductive film layer adjacent to a conductive film layer where the gate of the drive transistor M0 is lcoated in the display panel 01. That is to say, the conductive film layer of the first portion L11 of the first signal line L1 is a conductive film layer adjacent to a conductive film layer of the scanning lines S0 in the display panel 01.

As shown in FIG. 6, the second portion L12 of the first signal line L1 is located on a side of the film layer of the first portion L11 away from the substrate 10. Since the first portion L11 of the first signal line L1 and the scanning lines S0 are respectively located at two adjacent conductive film layers and the second portion L12 is provided on a side of the scanning lines S0 away from the substrate 10, it is possible for the film layer where the second portion L12 is provided to have more options, or it is possible to provide the second portion L12 in a more desirable film layer as needed.

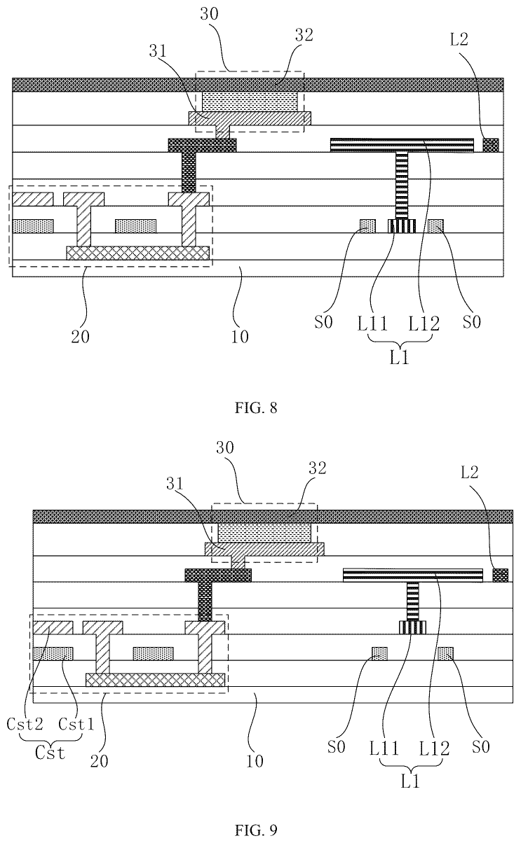

FIG. 7 is a schematic diagram of a display panel provided by an embodiment of the present disclosure, and FIG. 8 is a schematic cross-sectional view taken along a direction C1-C2 shown in FIG. 7.

In an embodiment of the present disclosure, in conjunction with FIG. 7 and FIG. 8, the display panel 01 further includes a plurality of data lines L2. The second portion L12 of the first signal line L1 may be located in a same film layer as the data lines L2. Since the data lines L2 usually extend along the second direction Y, providing the second portion L12 and the data lines L2 in the same layer does not pose a risk of a cross-short circuit therebetween and is easy to achieve.

In a technical solution corresponding to the embodiment, as shown in FIG. 8, the first portion L11 of the first signal line L1 and the scanning lines S0 are located in a same film layer, and the second portion L12 and the data lines L2 are provided in the same layer.

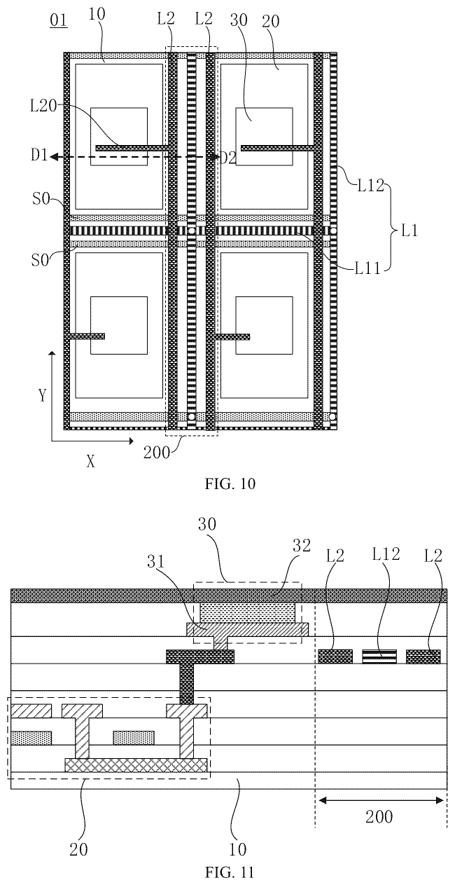

FIG. 9 is another schematic cross-sectional view taken along the direction C1-C2 shown in FIG. 7.

In a technical solution corresponding to the embodiment, as shown in FIG. 9, the first portion L11 of the first signal line L1 and the second electrode plate Cst2 of the storage capacitor Cst are located in a same film layer, and the second portion L12 and the data lines L2 are provided in a same layer.

FIG. 10 is another schematic diagram of a display panel provided by an embodiment of the present disclosure, and FIG. 11 is a schematic cross-sectional view taken along a direction D1-D2 shown in FIG. 10.

In an implementation of the embodiment, in conjunction with FIG. 10 and FIG. 11, two data lines L2 are included between the pixel circuits 20 arranged along the first direction X, and the second portion L12 of the first signal line L1 may be located between the two data lines L2 and provided in a same layer as the two data lines L2. That is to say, at least two data lines L2 and the second portion L12 located between the two data lines L2 and provided in a same layer as the two data lines L2 are arranged in a concentration manner, and simultaneously arranged between the pixel circuits 20 arranged along the first direction X in a concentration manner. As shown in FIG. 10, a spacer region 200 is included between the pixel circuits 20 arranged adjacently along the first direction X. At least two data lines L2 and the second portion L12 located between the two data lines L2 and provided in the same layer as the data lines L2 are provided in a same spacer region 200.

As shown in FIG. 10, the pixel circuits 20 arranged along the second direction Y may be electrically connected to two data lines L2 alternately, that is, two adjacent pixel circuits 20 arranged along the second direction Y may be electrically connected to different data lines L2. In this way, it is possible to enable the display panel 01 to have a higher refresh rate. At this time, two adjacent pixel circuits 20 arranged along the second direction Y and located in a same column are respectively electrically connected to data lines L2 located on different sides thereof, thus a distance from at least one data line L2 to the data write transistor M1 is larger, and the at least one data line L2 needs to include a protrusion portion L20 with a large overlapping area with the pixel circuit 20 to achieve connection to the data write transistor M1. The protrusion portion L20 extends substantially along the first direction X. Therefore, when the second portion L12 of the first signal line L1 is located in a same film layer as the data lines L2, the second portion L12 being located between the above-mentioned two adjacent data lines L2 can reduce the risk of a short circuit between the second portion L12 and the data lines L2.

When the second portion L12 of the first signal line L1 is located between the pixel circuits 20 arranged along the first direction X, a via between the second portion L12 and the first portion L11 that are electrically connected for achieving the electrical conduction therebetween may avoid the locations of the pixel circuits 20. This setting is easy to achieve and reduces the risk of a short circuit with another conductive structure.

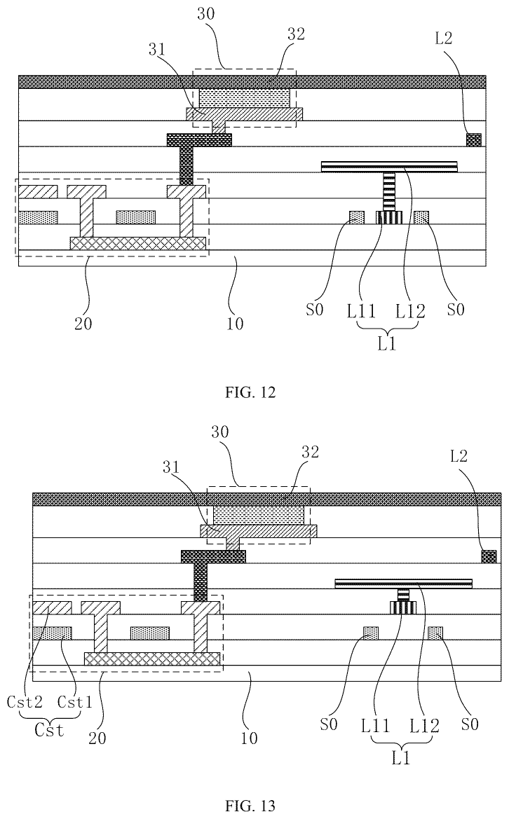

FIG. 12 is another schematic cross-sectional view taken along a direction C1-C2 shown in FIG. 7, and FIG. 13 is another schematic cross-sectional view taken along the direction C1-C2 shown in FIG. 7.

In an embodiment of the present disclosure, in conjunction with FIG. 7, FIG. 12, and FIG. 13, the display panel 01 further includes a plurality of data lines L2. The second portion L12 of the first signal line L1 is located on a side of a film layer of the data lines L2 close to the substrate 10. In the embodiment, the second portion L12 of the first signal line L1 may be closer to the scanning lines S0, that is, closer to the first portion L11 provided in a same layer as the scanning lines S0 or closer to the first portion L11 adjacent to the scanning lines S0, and thus it is easy to achieve the electrical connection between the first portion L11 and the second portion L12 located in different film layers.

In a technical solution corresponding to the embodiment, as shown in FIG. 12, the first portion L11 of the first signal line L1 is located in a same film layer as the scanning line S0, and the second portion L12 is located on the side of the film layer of the data line L2 close to the substrate 10.

In a technical solution corresponding to the embodiment, as shown in FIG. 13, the first portion L11 of the first signal line L1 is located in a same film layer as the second electrode plate Cst₂ of the storage capacitor Cst, and the second portion L12 is located on the side of the film layer of the data lines L2 close to the substrate 10.

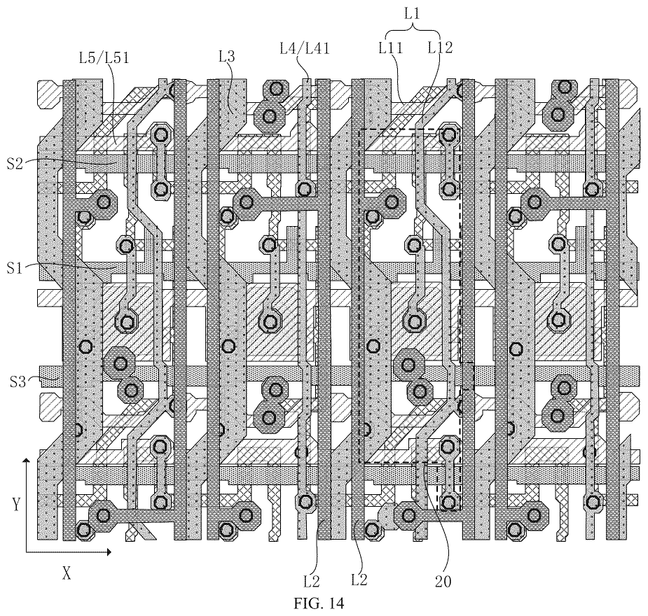

FIG. 14 is a schematic layout of a display panel provided by an embodiment of the present disclosure. It should be noted that, for clarity of illustration, a same filling pattern is used for structures located in a same film layer in the layout provided in this specification.

In an implementation of the embodiment, as shown in FIG. 14, for the data line L2 and the second portion L12 of the first signal line L1 which are adjacently provided, an overlapping area between the second portion L12 and the pixel circuit 20 is larger than an overlapping area between the data line L2 and the pixel circuit 20. That is to say, along the first direction X, the data line L2 is closer to an edge position of the pixel circuit 20, and the second portion L12 is closer to a central position of the pixel circuit 20. Since a signal transmitted by the first signal line L1 is substantially a stable signal, even if the first signal line L1 overlaps the pixel circuit 20 more, the performance of the pixel circuit 20 will not be affected too much, and the first signal line L1 can be prevented from occupying extra space in the first direction X.

Optionally, as shown in FIG. 14, the second portion L12 of the first signal line L1 substantially does not overlap the data line L2 along a direction perpendicular to a plane of the display panel 01.

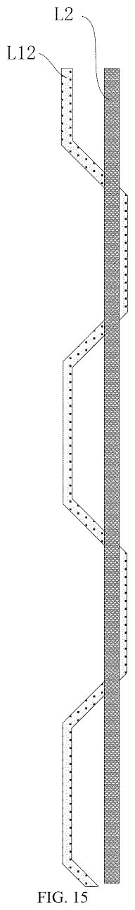

FIG. 15 is another schematic layout of a display panel provided by an embodiment of the present disclosure.

Optionally, as shown in FIG. 15, the second portion L12 of the first signal line L1 may alternatively overlap the data line L2 along a direction perpendicular to a plane of the display panel 01.

In the embodiment of the present disclosure, although the second portion L12 of the first signal line L1 overlaps the pixel circuit 20 along the direction perpendicular to the plane of the display panel, the via for achieving the electrical connection between the second portion L12 and the first portion L11 of the first signal line L1 may be provided outside a region of the pixel circuit 20. In this way, the difficulty of designing the via and the impact of the via on the design of the pixel circuit 20 are reduced.

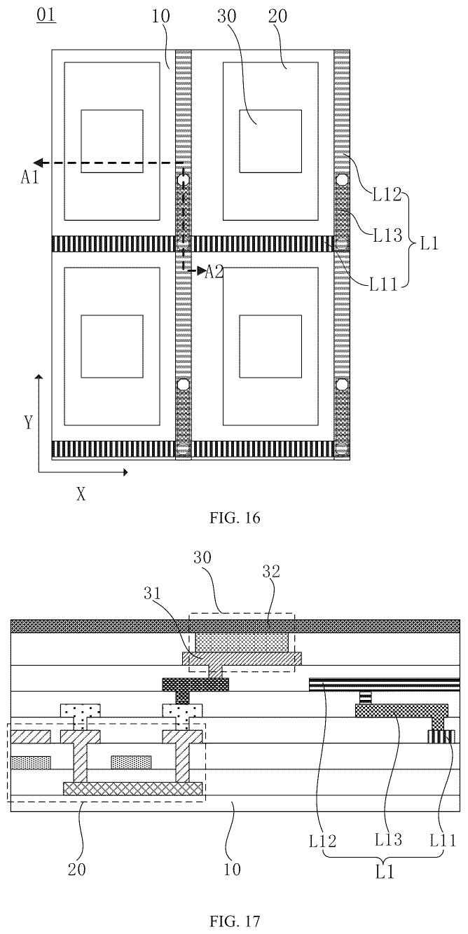

FIG. 16 is another schematic diagram of a display panel provided by an embodiment of the present disclosure, and FIG. 17 is a schematic cross-sectional view taken along a direction A1-A2 shown in FIG. 16.

In an embodiment of the present disclosure, in conjunction with FIG. 16 and FIG. 17, the first signal line L1 includes connection portions L13. The connection portion L13 is located between a film layer of the first portion L11 and a film layer of the second portion L12. The connection portion L13 is configured to connect the first portion L11 and the second portion L12. Specifically, the connection portion L13 has one end connected to the first portion L11 and the other end connected to the second portion L12.

As such, the connection portion L13 may be considered as a transfer connection structure located between the first portion L11 and the second portion L12. When the first portion L11 and the second portion L12 are electrically connected through the transfer connection structure located between the film layer of the first portion L11 and the film layer of the second portion L12, it is possible to provide a conductive yield of a conductive structure in the via between the first portion L11 and the second portion L12 for achieving the electrical connection therebetween. In addition, the two ends of the connection portion L13 are respectively connected to the first portion L11 and the second portion L12, such that the via for achieving the connection between the first portion L11 and the connection portion L13 and the via for achieving the connection between the second portion L12 and the connection portion L13 are arranged in a more dispersed manner, avoiding a problem that the area of the vias is too large when the vias are required to penetrate through a larger number of film layers. This avoids the occurrence of the vias of too large area that are easily recognized by human eyes and prevents the vias of too large area from affecting the provision of other structures in the display panel 01.

In an implementation of the embodiment, an extension direction of the connection portion L13 is the same as an extension direction of the second portion L12, and the second portion L12 overlaps the connection portion L13 along a direction perpendicular to a plane of the display panel 01. That is, at least a portion of the connection portion L13 that is close to the second portion L12 is shielded by the second portion L12, and the shielded region extends along the extension direction of the connection portion L13, which avoids the connection portion L13 from excessively occupying the area of the plane of the display panel 01.

Optionally, the second portion L12 covers the connection portion L13 along the direction perpendicular to the plane of the display panel 01. As such, the connection portion L13 is located on a side of the second portions L12 close to the substrate 10 and shielded by the first portion L12. This setting facilitates the achievement of the electrical connection between the connection portion L13 and the second portion L12 through the via, and the connection portion L13 does not additionally occupy the area of the plane of the display panel 01.

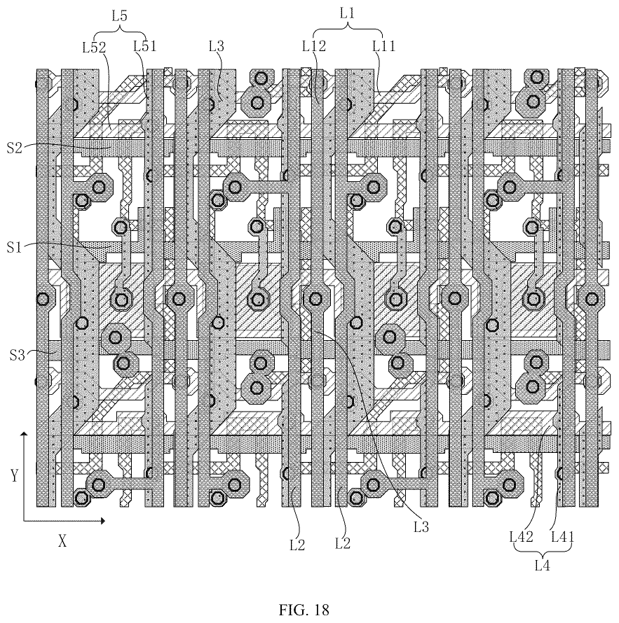

FIG. 18 is another schematic layout of a display panel provided by an embodiment of the present disclosure.

In a technical solution corresponding to the embodiment, as shown in FIG. 18, two data lines L2 are included between adjacent pixel circuits 20 arranged along the first direction X, and the second portion L12 of the first signal line L1 is included between the two data lines L2. In addition, in the technical solution, the connection portion L13 can be located between the two data lines L2. Therefore, the connection portion L13 extends substantially along the second direction Y and is located between the adjacent pixel circuits 20 arranged along the first direction X.

Since the manner of providing the conductive structure between the adjacent pixel circuits 20 is relatively simple, when the connection portion L13 is provided between the adjacent pixel circuits 20, it is easy to achieve the connection between the first portion L11 and the second portion L12.

It should be noted that, two data lines L2 being included between adjacent pixel circuits 20 arranged along the first direction X does not mean that the two data lines L2 do not overlap the pixel circuits 20, but means that the two data lines L2 both overlap a region between the above-mentioned adjacent pixel circuits 20. Certainly, the two data lines L2 may alternatively not overlap the pixel circuits 20.

In this technical solution, the second portion L12 of the first signal line L1 and the data lines L2 may be provided in a same layer, and the connection portion L13 is located on a side of the data lines L2 close to the substrate 10.

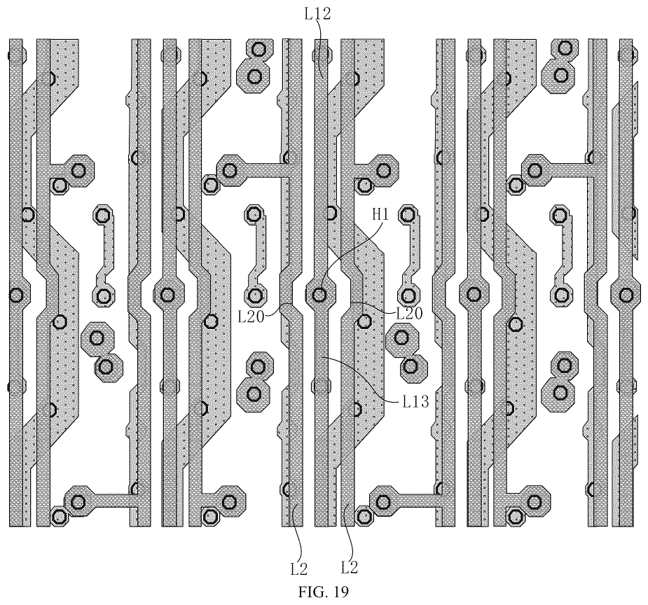

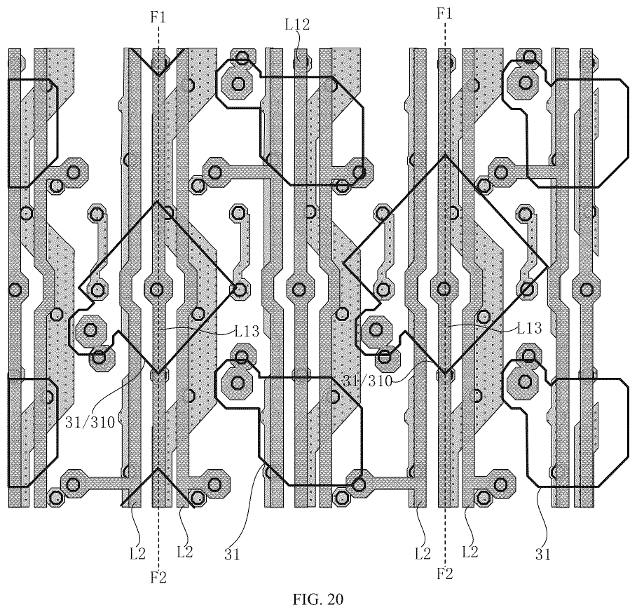

FIG. 19 is a schematic diagram of a part of a structure in FIG. 18.

As shown in FIG. 19, when the second portion L12 located in the same layer as the data lines L2 is electrically connected to the connection portion L13 through a first via H1, the data lines L2 located on two sides of the second portion L12 may be designed to avoid the location of the first via H1. As shown in FIG. 19, a portion of the data line L2 that is arranged adjacent to the first via H1 along the first direction X is bent toward a direction away from the first via H1 to form a bent portion L20, to avoid the region of the first via H1, thereby reducing the risk of a short circuit between a portion of the connection portion L13 that is located near the first via H1 and the data line L2.

In the embodiment of the present disclosure, the structure between the two data lines L2 located between the adjacent pixel circuits 20 is relatively simple, and especially, there are fewer vias. Therefore, when the connection portion L13 is located between the two data lines L2, it is easy for the connection portion L13 to be electrically connected to the first portion L11 and the second portion L12 through different vias.

FIG. 20 is another schematic diagram of a part of the structure in FIG. 18.

In a technical solution corresponding to the embodiment, as shown in FIG. 20, the first electrode 31 of at least one of the light-emitting devices 30 overlaps the connection portion L13 along the direction perpendicular to the plane of the display panel 01.

Optionally, the first electrode 31 of at least one of the light-emitting devices 30 covers the connection portion L13 along the direction perpendicular to the plane of the display panel 01. As shown in FIG. 20, the plurality of light-emitting devices 30 each include a first electrode 31, and the first electrode 31 covers at least a partial region of the connection portion L13. Optionally, the first electrode 31 completely covers the connection portion L13.

In an implementation of this technical solution, as shown in FIG. 20, the plurality of light-emitting devices 30 includes a first light-emitting device (a first electrode 31 of the first light-emitting device is shown in the figure). The first light-emitting device is symmetrical with respect to a first symmetry axis F1-F2. The first electrode 31 of the first light-emitting device covers at least a partial region of the connection portion L13 along the direction perpendicular to the plane of the display panel. An extension direction of the first symmetry axis F1-F2 is the same as an extension direction of the connection portion L13. Optionally, the first electrode 31 of the first light-emitting device covers the first via H1 along the direction perpendicular to the plane of the display panel, which can avoid/alleviate a problem of reflectivity difference caused by the first via. Optionally, the first symmetry axis F1-F2 overlaps the first via H1 along the direction perpendicular to the plane of the display panel, which can avoid/alleviate a problem of four-directional color deviation caused by the first via.

Optionally, as shown in FIG. 20, the first electrode 31 of the first light-emitting device overlaps two data lines L2 along the direction perpendicular to the plane of the display panel 01. The two data lines L2 are located on two sides of the first symmetry axis and symmetrical with respect to the first symmetry axis F1-F2. As such, the two data lines L2 located below the first electrode 31 of the first light-emitting device are symmetrically provided, which avoids a problem of height asymmetry at different locations of the first light-emitting device caused by the asymmetrical design of the data lines L2 below the first light-emitting device, and it is possible to ensure that the morphology of the first light-emitting device is symmetrical with respect to the first symmetry axis F1-F2.

It should be noted that, the symmetry described above is symmetry within a process error range.

In addition, since at least a partial region of the connection portion L13 is covered by the first electrode 31 of the first light-emitting device and the connection portion L13 is located between the two data lines L2, when the connection portion L13 and the data lines L2 are provided in a same layer, a film layer for carrying the first electrode 31 between the first electrode 31 of the first light-emitting device and the connection portion L13 as well as the data line L2 is relatively flat below the first electrode 31. Therefore, it is possible for the first light-emitting device to have a relatively uniform morphology to ensure its light-emitting performance.

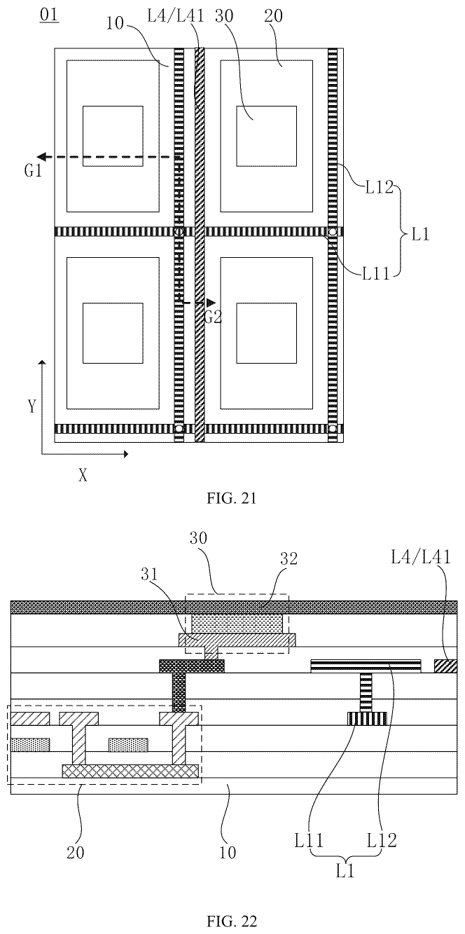

FIG. 21 is another schematic diagram of a display panel provided by an embodiment of the present disclosure, and FIG. 22 is a schematic cross-sectional view taken along a direction G1-G2 shown in FIG. 21.

In an embodiment of the present disclosure, as shown in FIG. 21 and FIG. 22, the display panel 01 includes a first reset line L4, the first reset line L4 includes third portions L41 extending along the second direction Y, and the second portion L12 and the third portion L41 are provided in a same layer. When both the third portion L41 and the second portion L12 extend along the second direction Y and are provided in the same layer, the second portion L12 and the third portion L41 can be prepared at the same time.

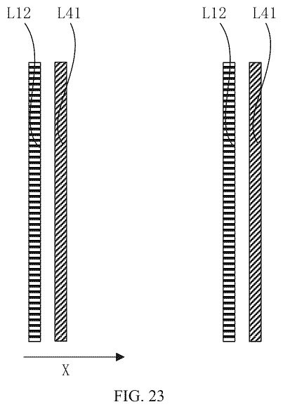

FIG. 23 is a schematic diagram of a partial structure in a display panel provided by an embodiment of the present disclosure.

In a technical solution corresponding to the embodiment, as shown in FIG. 14 and FIG. 23, the second portions L12 and the third portions L41 are alternately arranged in sequence along the first direction X.

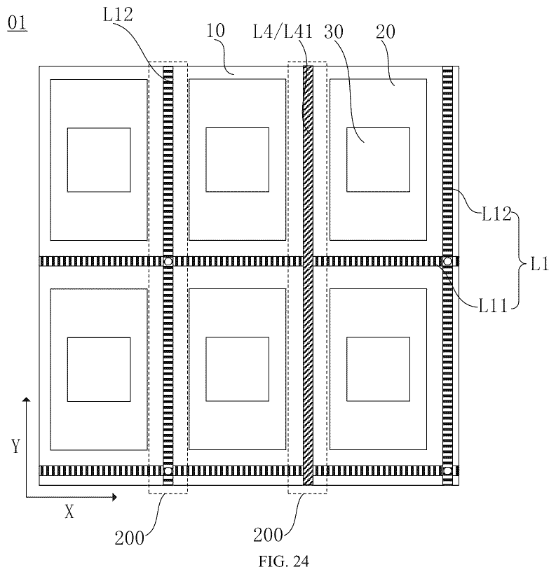

FIG. 24 is a schematic diagram of a display panel provided by an embodiment of the present disclosure.

In an implementation, as shown in FIG. 24, a spacer region 200 is included between pixel circuits 20 arranged adjacently along the first direction X, and the second portion L12 and the third portion L41 each may be provided in a spacer region 200.

In the implementation, the second portion L12 and the third portion L41 overlap different spacer regions 200, respectively, along a direction perpendicular to a plane of the display panel 01, that is, the second portion L12 and the third portion L41 are provided in different spacer regions 200, respectively.

When the second portions L12 and the third portions L41 are alternately provided along the first direction X, the number of the second portions L12 and the number of the third portions L41 are the same or differ by one or two. If two adjacent second portion L12 and third portion L41 are provided in a same spacer region 200, the width of the spacer region 200 is required to be larger, which is not conducive to achieving high resolution. In addition, with the alternate provision of the second portion L12 and the third portion L41 in different spacer regions 200, it is possible to ensure that the spacer regions 200 each have a small width. Meanwhile, it is possible to ensure that the number of the third portions L41 is sufficiently large, and in turn to make the reset line L4 have a smaller resistance and a signal transmitted therethrough has a small voltage drop.

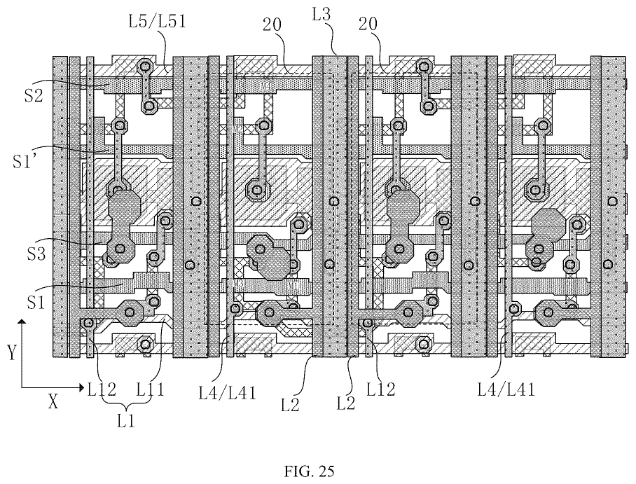

FIG. 25 is another schematic layout of a display panel provided by an embodiment of the present disclosure.

In an implementation, as shown in FIG. 25, the second portion L12 and the third portion L41 overlap different pixel circuits 20, respectively, along a direction perpendicular to a plane of the display panel 01, that is, the second portion L12 and the third portion L41 arranged adjacently along the first direction X are provided in regions of different pixel circuits 20 arranged adjacently along the first direction X.

If two adjacent second portion L12 and third portion L41 are provided compactly, for example, overlap a same pixel circuit 20, the total overlapping area between the pixel circuit 20 and the second portion L12 as well as the third portion L41 increases, which is not conducive to the achievement of the electrical connections between different transistors in the pixel circuit 20 and between the transistors and the signal lines and the like. By overlapping the second portion L12 and the third portion L41 with the pixel circuits 20 arranged along the first direction X, it is possible to avoid the excessive influence of the second portion L12 and the third portion L41 on the structure of the pixel circuits 20 to reduce the difficulty in designing the layout of the display panel.

It should be noted that, the gates of the data write transistor M1 and the threshold write transistor M2 in the pixel circuit 20 may be electrically connected to different scanning lines, respectively. For example, as shown in FIG. 25, the gate of the data write transistor M1 may be electrically connected to a scanning line S1, and the gate of the threshold write transistor M2 may be electrically connected to a scanning line S1′. It should also be noted that, the gates of the first reset transistor M3 and the second reset transistor M4 in the pixel circuit 20 may be electrically connected to different scanning lines, respectively. For example, as shown in FIG. 25, both the gate of the first reset transistor M3 and the gate of the data write transistor M1 in the pixel circuit 20 may be electrically connected to a scanning line S1, and the gate of the second reset transistor M4 may be electrically connected to a scanning line S2.

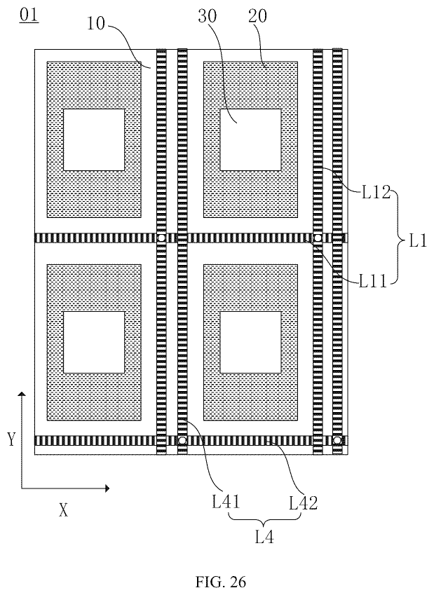

FIG. 26 is another schematic diagram of a display panel provided by an embodiment of the present disclosure.

In a technical solution corresponding to the embodiment, as shown in FIG. 26, the first reset line L4 further includes fourth portions L42 extending along the first direction X. The fourth portion L42 and the first portion L11 are located in a same film layer. As such, the fourth portion L42 and the first portion L11 can be prepared at the same time. In the implementation, the first reset line L4 may include third portions L41 and fourth portions L42 provided in different layers and provided to intersect with each other. Therefore, the loss of a signal transmitted through the first reset line L4 is relatively small.

For the manner in which the third portion L41 is electrically connected to the fourth portion L42, reference can be made to the manner in which the first portion L11 is electrically connected to the second portion L12. The two manners are the same. In addition, for the manner of provision of the third portion L41 and the fourth portion L42, reference can be made to the manner of provision of the first portion L11 and the second portion L12, which will not be further discussed herein.

In a technical solution corresponding to the embodiment, as shown in FIG. 14, FIG. 18, and FIG. 25, the display panel 01 further includes a second reset line L5. The second reset line L5 includes fifth portions L51 extending along the first direction X. The fifth portion L51 and the first portion L11 are located in a same film layer. As such, the fifth portion L51 and the first portion L11 can be prepared at the same time.

In some embodiments, as shown in FIG. 18, the second reset line L5 includes the fifth portions L51 extending along the first direction X and sixth portions L52 extending along the second direction Y, and the fifth portion L51 and the sixth portion L52 are electrically connected. Therefore, the loss of a signal transmitted through the second reset line L5 is reduced.

In addition, the fifth portion L51 may be provided in a same layer and in a same direction as at least one of the fourth portion L42 and the first portions L11. The sixth portion L52 is provided in a same layer and in a same direction as at least one of the third portion L41 and the second portion L12. For example, as shown in FIG. 18, the fifth portion L51 is provided in a same layer and in a same direction as both the fourth portion L42 and the first portion L11, and the sixth portion L52 is provided in a same layer and in a same direction as the third portion L41.

In some embodiments, as shown in FIG. 14 and FIG. 25, the second reset line L5 includes the fifth portions L51 extending along the first direction X and does not include sixth portions L52 extending along the second direction Y. The fifth portion L51 may be provided in a same layer and in a same direction as at least one of the fourth portion L42 and the first portion L11. For example, as shown in FIG. 14 and FIG. 25, the fifth portion L51 is provided in a same layer and in a same direction as both the fourth portion L42 and the first portion L11.

In addition, FIG. 3 shows that the first reset line L4 is electrically connected to the first electrode of the first reset transistor M3 in the pixel circuit 20, and the second reset line L5 may be electrically connected to the first electrode of the second reset transistor M4 in the pixel circuit 20.

In some embodiments, the first reset line L4 may be electrically connected to the first electrode of the second reset transistor M4 in the pixel circuit 20, and the second reset line L5 may be electrically connected to the first electrode of the first reset transistor M3 in the pixel circuit 20. As such, a reset signal line that transmits a reset voltage to the gate of the drive transistor M0 is the first reset line L4 including the third portions L41 extending along the second direction Y, and a reset signal line that transmits a reset voltage to the first electrode of the light-emitting device 30 is the second reset line L5 extending along the first direction X.

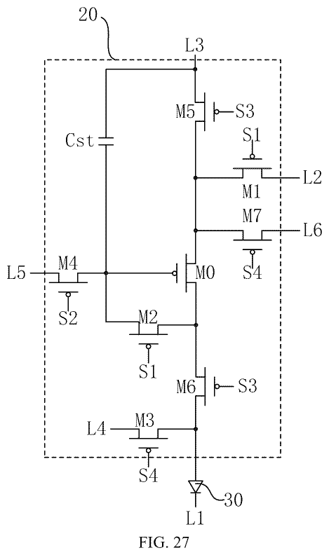

FIG. 27 is an equivalent circuit diagram of a pixel circuit included in a display panel provided by an embodiment of the present disclosure.

A difference between FIG. 27 and FIG. 3 is that the pixel circuit 20 shown in FIG. 27 further includes a bias transistor M7. The bias transistor M7 has a first electrode electrically connected to a second signal line L6 and a second electrode electrically connected to the drive transistor M0. The bias transistor M7 is configured to provide a bias voltage transmitted through the second signal line L6 to the drive transistor M0, to bias the drive transistor M0 to alleviate a threshold drift problem of the drive transistor M0.

At least a part of the operation cycle of the pixel circuit 20 may also include a bias stage. In the bias stage, a fourth scanning line S4 electrically connected to a gate of the bias transistor M7 transmits an enable signal for controlling the bias transistor M7 to be turned on. The bias stage may be after the light-emitting stage. When one operation cycle of the pixel circuit 20 includes a plurality of light-emitting stages, the bias stage may fall between adjacent ones of the plurality of light-emitting stages.

It should be noted that, FIG. 27 shows that the second electrode of the bias transistor M7 is electrically connected to the first electrode of the drive transistor M0. In some embodiments, the second electrode of the bias transistor M7 may be electrically connected to the second electrode of the drive transistor M0.

In addition, the gate of the first reset transistor M3 may be electrically connected to a same scanning line as the gate of the bias transistor M7. For example, both are electrically connected to the fourth scanning line S4.

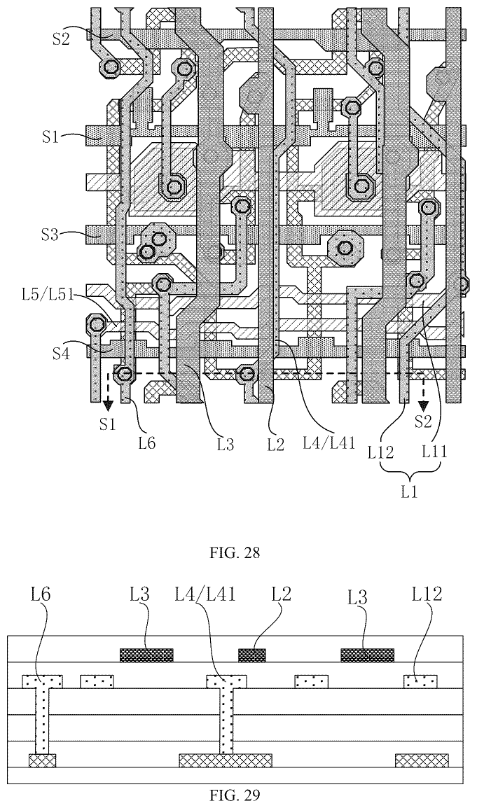

FIG. 28 is another schematic layout of a display panel provided by an embodiment of the present disclosure, and FIG. 29 is a schematic cross-sectional view taken along a direction S1-S2 shown in FIG. 28.

In an embodiment of the present disclosure, in conjunction with FIG. 28 and FIG. 29, the second signal line L6 configured to transmit a bias voltage extends along the second direction Y, and the second portion L12 of the first signal line L1 and the second signal line L6 are provided in a same layer. That is, the second portion L12 of the first signal line L1 and the second signal line L6 have a same extension direction and are provided in a same layer. Therefore, the second signal line L6 and the second portion L12 of the first signal line L1 may be prepared at the same time to be formed.

The fourth scanning line S4 electrically connected to the gate of the bias transistor M7 may be provided in a same layer as the first scanning line S1, the second scanning line S2, and the third scanning line S3.

The second portion L12 of the first signal line L1 may be provided in a same layer as the data line L2. As such, the second signal line L6 may be provided in the same layer as the data line L2.

In addition, the second portion L12 of the first signal line L1 may be provided in a same layer as the third portion L41 of the first reset line L4. As such, the second signal line L6 may be provided in a same layer as the third portion L41 of the first reset line L4. At this time, the conductive film layer of the second portion L12 of the first signal line L1 is provided with a higher number of types of signal lines. To make the design of the signal lines in the conductive film layer less difficult and the interference between different signal lines less, the data line L2 and the supply voltage line L3 may be provided in a conductive film layer different from the foregoing conductive film layer. For example, as shown in FIG. 28, the second portion L12 of the first signal line L1, the third portion L41 of the first reset line L4, and the second signal line L6 are provided in one conductive film layer at the same time, and the data line L2 and the supply voltage line L3 are provided in another conductive film layer.

In an embodiment of the present disclosure, a first electrode plate of the storage capacitor Cst is provided in a same layer as the gate of the drive transistor M0. As such, the gate of the drive transistor M0 may be considered as a part of the first electrode plate. The storage capacitor Cst is configured to maintain a potential of the gate of the drive transistor M0. A change in the potential of the gate of the drive transistor M0 will seriously affect a light-emitting drive current output by the pixel circuit 20. By maintaining the stability of the potential of the gate of the drive transistor M0, it is possible to improve the driving performance of the pixel circuit 20.

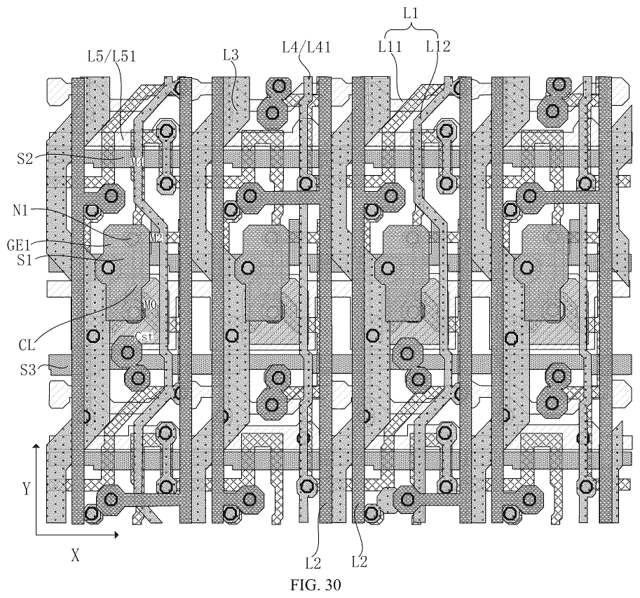

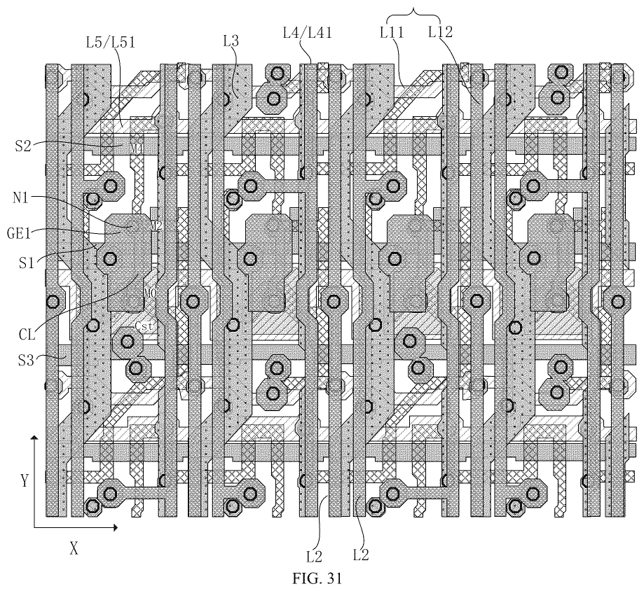

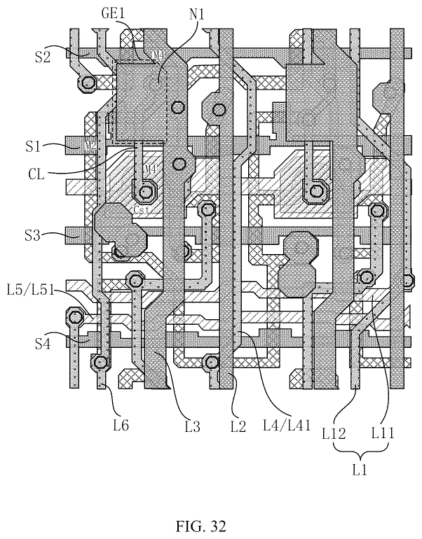

FIG. 30 is another schematic layout of a display panel provided by an embodiment of the present disclosure, FIG. 31 is another schematic layout of a display panel provided by an embodiment of the present disclosure, and FIG. 32 is another schematic layout of a display panel provided by an embodiment of the present disclosure.

As shown in FIG. 30-FIG. 31, a gate of the drive transistor M0 is electrically connected to a first node N1 in a semiconductor layer through a conductive line CL. The first node N1 in the semiconductor layer may be a portion electrically connected to the conductive line and located in a semiconductor layer of a transistor electrically connected to the gate of the drive transistor M0. For example, the first node N1 is a node electrically connected to the conductive line CL and located in a semiconductor layer of the second reset transistor M4, and/or the first node N1 is a node electrically connected to the conductive line CL and located in a semiconductor layer of the threshold write transistor M2.

It can be seen that a change in a potential of the first node N1 may directly affect a potential of the gate of the drive transistor M0 through the conductive line CL. Therefore, in the embodiment of the present disclosure, the display panel further includes a first isolation electrode GE1. The first isolation electrode GE1 covers the first node N1 along a direction perpendicular to a plane of the display panel, to shield the influence of other signal lines on the potential of the first node N1 and in turn to alleviate a floating problem of the potential of the gate of the drive transistor M0.

In the embodiment, the first isolation electrode GE1 may be located between the film layer of the data line L2 and a film layer of the gate of the drive transistor M0, or the first isolation electrode GE1 and the data line L2 are located in a same film layer. The first isolation electrode GE1 may be electrically connected to the supply voltage line L3 to obtain a constant potential and in turn to achieve a shielding effect.

In some embodiments, as shown in FIG. 32, the supply voltage line L3 may protrude toward the location where the first node N1 is located to form the first isolation electrode GE1. At this time, the first isolation electrode GE1 and the supply voltage line L3 may be provided in a same layer.

In some embodiments, as shown in FIG. 30 and FIG. 31, the first isolation electrode GE1 and the supply voltage line L3 may be provided in different layers, and the first isolation electrode GE1 is electrically connected to the supply voltage line L3 through a via.

The first isolation electrode GE1 is located between the film layer of the data line L2 and the film layer of the gate of the drive transistor M0, or the isolation electrode GE1 and the data line L2 are located in a same film layer.

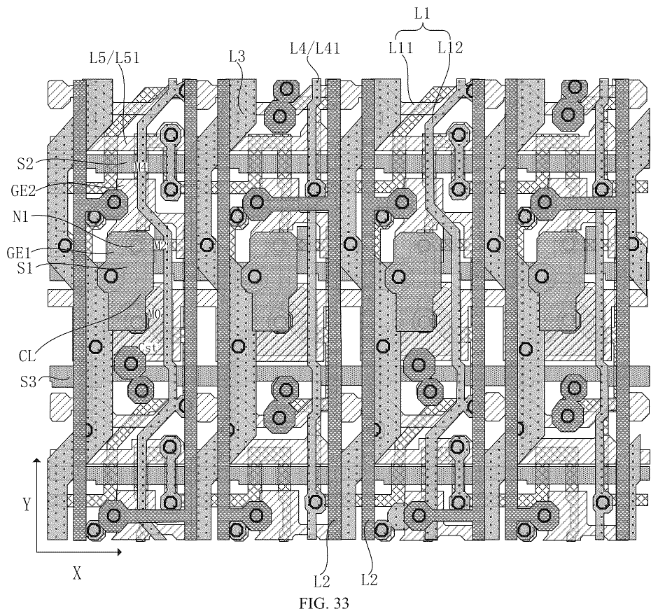

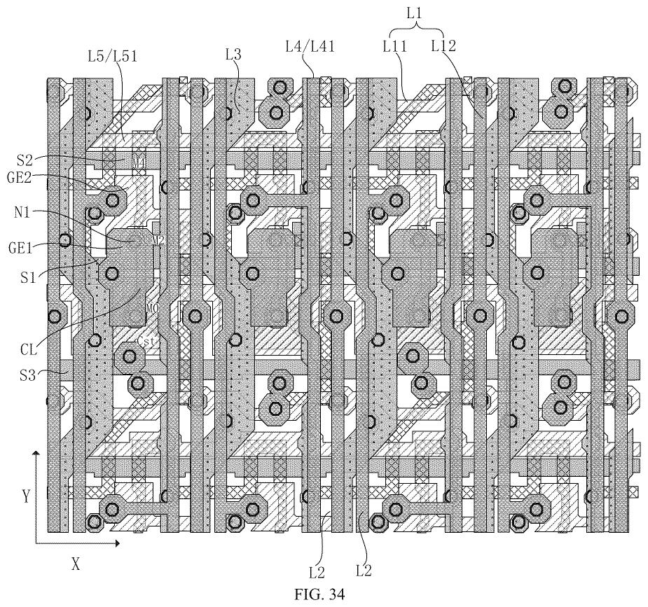

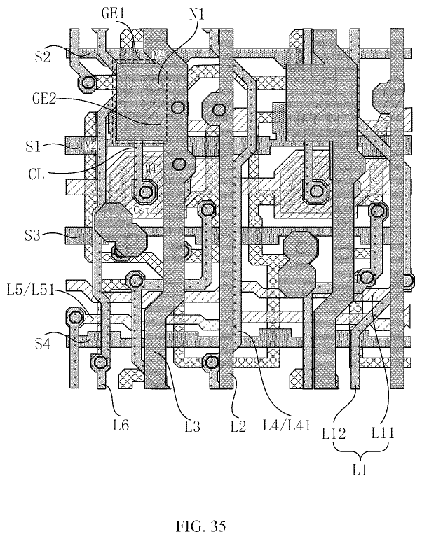

FIG. 33 is another schematic layout of a display panel provided by an embodiment of the present disclosure, FIG. 34 is another schematic layout of a display panel provided by an embodiment of the present disclosure, and FIG. 35 is another schematic layout of a display panel provided by an embodiment of the present disclosure.

As shown in FIG. 33-FIG. 35, the display panel may further include a second isolation electrode GE2. The second isolation electrode GE2 may overlap a portion connected to a first node N1 in a semiconductor layer and located in the first node N1 away from the conductive line CL along a direction perpendicular to a plane of the display panel, and in turn it is possible to effectively shield the influence of other signals on the potential of the first node N1.

The second isolation electrode GE2 may be provided in a same layer as the first portion L11 of the first signal line L1. In addition, the second isolation electrode GE2 may also be electrically connected to the supply voltage line L3 through a via.

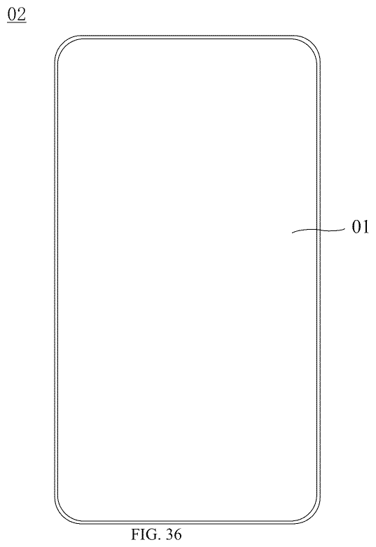

FIG. 36 is a schematic diagram of a display apparatus provided by an embodiment of the present disclosure.

An embodiment of the present disclosure provides a display apparatus. As shown in FIG. 30, the display apparatus 02 includes the display panel 01 provided by the foregoing embodiments. The display apparatus 02 provided by the embodiment of the present disclosure may be an electronic device, such as a mobile phone, a computer, a television, or a vehicle-mounted display apparatus. This is not specifically limited in the embodiments of the present disclosure.

In the embodiment of the present disclosure, the first signal line L1 in the display apparatus 02 is of a grid-like structure. Therefore, a signal transmitted through the first signal line L1 has a small voltage drop. By providing the first portion L11 and the second portion L12 extending along different directions of the first signal line L1 in different conductive film layers, it is possible for the first portion L11 to be located in a same film layer as another conductive structure, and it is possible for the second portion L12 to be located in a same film layer as another conductive structure, which may neither increase the thickness of the display panel 01 nor increase manufacturing process or cost. In addition, since the first signal line L1 is electrically connected to the second electrode 32 of the light-emitting device 30, that is, the first signal line L1 is configured to transmit a substantially constant supply voltage, when the first portion L11 and the second portion L12 of the first signal line L1 are provided in different film layers, the performance of signal lines or functional devices in a same layer as and/or in a layer adjacent to the first portions L11 and the second portions L12, respectively, may not be substantially affected.

The above descriptions are merely preferred embodiments of the present disclosure and are not intended to limit the present disclosure. Any modification, equivalent replacement and improvement within the spirit and principle of the present disclosure shall be included within the protection scope of the present disclosure.

What is claimed is:

1. A display panel, comprising: a substrate; a plurality of pixel circuits, a plurality of light-emitting devices, and a first signal line that are located on a side of the substrate;
wherein an output terminal of each of the pixel circuits is electrically connected to a first electrode of one of the light-emitting devices, and a second electrode of each of the plurality of light-emitting devices is electrically connected to the first signal line; and the first signal line comprises first portions and second portions provided in different layers and electrically connected, the first portions extend along a first direction, the second portions extend along a second direction, and the first direction intersects the second direction.

2. The display panel according to claim 1, further comprising a plurality of scanning lines extending along the first direction, the first portions and the scanning lines are located in a same film layer, and the second portions are located on a side of the film layer away from the substrate.

3. The display panel according to claim 1, wherein each of the pixel circuits comprises a drive transistor and a storage capacitor, and a first electrode plate of the storage capacitor and a gate of the drive transistor are provided in a same layer and electrically connected; and
the first portions and a second electrode plate of the storage capacitor are located in a same film layer, and the second portions are located on a side of the film layer of the first portions away from the substrate.

4. The display panel according to claim 2, further comprising a plurality of data lines; and
the second portions and the data lines are located in a same film layer, or the second portions are located on a side of a film layer of the data lines close to the substrate.

5. The display panel according to claim 3, further comprising a plurality of data lines; and
the second portions and the data lines are located in a same film layer, or the second portions are located on a side of a film layer of the data lines close to the substrate.

6. The display pane according to claim 1, wherein the first signal line comprises connection portions, and one end of each of the connection portions is connected to one of the first portions and the other end of each of the connection portions is connected to one of the second portions; and
the connection portions are located between a film layer of the first portions and a film layer of the second portions.

7. The display panel according to claim 6, wherein an extension direction of the connection portions is the same as an extension direction of the second portions; and the second portion overlaps the connection portion along a direction perpendicular to a plane of the display panel.

8. The display panel according to claim 7, wherein the second portion covers the connection portion along the direction perpendicular to the plane of the display panel.

9. The display panel according to claim 6, wherein the first electrode of at least one of the light-emitting devices overlaps the connection portion along a direction perpendicular to a plane of the display panel.

10. The display panel according to claim 9, wherein the first electrode of the at least one of the light-emitting devices covers the connection portion along the direction perpendicular to the plane of the display panel

11. The display panel according to claim 9, wherein the plurality of light-emitting devices comprises a first light-emitting device; and a first electrode of the first light-emitting device covers the connection portion along the direction perpendicular to the plane of the display panel; and
the first light-emitting device is symmetrical with respect to a first symmetry axis, and an extension direction of the first symmetry axis is the same as an extension direction of the connection portion.

12. The display panel according to claim 11, wherein the first electrode of the first light-emitting device overlaps two of the data lines along the direction perpendicular to the plane of the display panel; and the two of the data lines are respectively located on two sides of the first symmetry axis and are symmetrical with respect to the first symmetry axis.

13. The display panel according to claim 1, further comprising a first reset line, and the first reset line comprises third portions extending along the second direction; and the second portions and the third portions are provided in a same film layer.

14. The display panel according to claim 13, wherein the second portions and the third portions are alternately arranged along the first direction.

15. The display panel according to claim 14, wherein a spacer region included between pixel circuits arranged adjacently along the first direction; and the second portion and the third portion respectively overlap different spacer regions along a direction perpendicular to a plane of the display panel; or
the second portion and the third portion respectively overlap different pixel circuits arranged along the first direction along a direction perpendicular to a plane of the display panel.

16. The display panel according to claim 13, wherein the first reset line further comprises fourth portions extending along the first direction; and the first portions and the fourth portions are located in a same film layer.

17. The display panel according to claim 13, wherein the display panel further comprises a second reset line, the second reset line comprises fifth portions extending along the first direction, and the first portions and the fifth portions are located in a same film layer.

18. The display panel according to claim 1, further comprising a second signal line;
each of the pixel circuits comprises a drive transistor and a bias transistor; the bias transistor includes a first electrode electrically connected to the second signal line and a second electrode electrically connected to the drive transistor, and the bias transistor is configured to provide a bias voltage transmitted through the second signal line to the drive transistor; and
the second signal line extends along the second direction, and the second portions and the second signal line are provided in a same film layer.

19. A display apparatus, comprising a display panel comprising: a substrate; a plurality of pixel circuits, a plurality of light-emitting devices, and a first signal line that are located on a side of the substrate;
wherein an output terminal of each of the pixel circuits is electrically connected to a first electrode of one of the light-emitting devices, and a second electrode of each of the plurality of light-emitting devices is electrically connected to the first signal line; and the first signal line comprises first portions and second portions provided in different layers and electrically connected, the first portions extend along a first direction, the second portions extend along a second direction, and the first direction intersects the second direction.
